(19) United States
(12) Patent Application Publication
(10) Pub. No.: US 2025/0380585 A1
(43) Pub. Date: Dec. 11, 2025

(54) DISPLAY DEVICE AND ELECTRONIC DEVICE INCLUDING THE SAME

(71) Applicant: Samsung Display Co., LTD., Yongin-si (KR)

(72) Inventors: NAHYEON CHA, Yongin-si (KR); SUNKWUN SON, Yongin-si (KR)

(21) Appl. No.: 19/074,618

(22) Filed: Mar. 10, 2025

(30) Foreign Application Priority Data
Jun. 7, 2024 (KR) 10-2024-0074167

(51) Int. Cl. H10K 59/131; H10K 59/121

(52) U.S. Cl. CPC H10K 59/131; H10K 59/1213

(57) ABSTRACT

A display device includes: a first pixel circuit including: a first driving transistor that generates a driving current, a first-first switching transistor including a first active pattern and a portion of a first gate signal line overlapping the first active pattern, and a second-first switching transistor including a portion of a second active pattern spaced apart from the first active pattern and a portion of a second gate signal line overlapping the second active pattern, and facing the first-first switching transistor, a second pixel circuit next to the first pixel circuit in a first direction and including: a second driving transistor that generates a driving current and a second switching transistor including a third active pattern spaced apart from the first and second active patterns and a portion of the second gate signal line overlapping the third active pattern, and a light-emitting element on the first and second pixel circuits.

This application claims priority to Korean Patent Application No. 10-2024-0074167, filed on Jun. 7, 2024, the and all the benefits accruing therefrom under 35 U.S.C. § 119, the content of which in its entirety is herein incorporated by reference.

### BACKGROUND

### 1. Field

Embodiments relate generally to a display device. More particularly, embodiments relate to a display device that provides visual information.

### 2. Description of the Related Art

As information technology develops, the importance of display devices, which are communication media between users and information, is being highlighted. Accordingly, the use of display devices such as a liquid crystal display device, an organic light-emitting display device, a plasma display device, and the like is increasing.

Recently, research on integrating multiple pixels within a substantially narrow area is being actively conducted to implement high-resolution display devices.

### SUMMARY

Embodiments provide a display device realized with high-resolution and high-integration.

A display device in embodiments of the disclosure includes a first pixel circuit including: a first driving transistor that generates a driving current, a first-first switching transistor including a first active pattern and a portion of a first gate signal line overlapping the first active pattern and a second-first switching transistor including a portion of a second active pattern spaced apart from the first active pattern and a portion of a second gate signal line overlapping the second active pattern, and facing the first-first switching transistor with the first driving transistor in between in a plan view, a second pixel circuit next (adjacent) to the first pixel circuit in a first direction and including: a second driving transistor that generates a driving current and a second switching transistor including a third active pattern spaced apart from the first and second active patterns and a portion of the second gate signal line overlapping the third active pattern, and a light-emitting element disposed on the first and second pixel circuits.

In an embodiment, the first pixel circuit may be disposed in a N-th pixel row (where N is a natural number), the second pixel circuit may be disposed in a (N+1)-th pixel row next (adjacent) to the N-th pixel row, the first gate signal line may provide a first write gate signal to the first pixel circuit, and the second gate signal line may provide a second write gate signal to the first and second pixel circuits.

In an embodiment, each of the first gate signal line and the second gate signal line may extend in a second direction crossing the first direction.

In an embodiment, the first driving transistor may include another portion of the second active pattern, and a gate electrode disposed on the second active pattern and overlapping the second active pattern.

In an embodiment, the first active pattern may include a third area and a fourth area doped with impurities and spaced apart from each other and the second active pattern may include a first area, a second area, and a fifth area doped with impurities and spaced apart from each other. The display device may further include a connection pattern connected to the fourth area of the first active pattern through a first contact hole and connected to the fifth area of the second active pattern through a second contact hole.

In an embodiment, the portion of the second active pattern of the second-first switching transistor may include the second area and the fifth area, another portion of the second active pattern of the first driving transistor may include the first area and second area, the gate electrode may overlap the third area of the first active pattern in the plan view, and the second area of the second active pattern may be disposed between the gate electrode and the fifth area of the second active pattern in the plan view.

In an embodiment, the connection pattern may be disposed on the first and second gate signal lines.

In an embodiment, the first pixel circuit may further include a program capacitor including the connection pattern and a portion of a data line disposed on the connection pattern and overlapping the connection pattern in the plan view.

In an embodiment, a portion of the second active pattern overlapping the gate electrode may have a U-shape in the plan view.

In an embodiment, the first pixel circuit may further include a storage capacitor including the gate electrode and a portion of an initialization voltage line disposed on the gate electrode and overlapping the gate electrode in the plan view.

In an embodiment, the storage capacitor may further include a portion of a capacitor electrode connected to the first active pattern through a contact hole and overlapping the initialization voltage line in the plan view.

In an embodiment, the initialization voltage line may extend in a second direction intersecting the first direction.

In an embodiment, the first, second, and third active patterns may include a silicon semiconductor.

A display device in embodiments of the disclosure includes a substrate including a first pixel circuit area and a second pixel circuit area next (adjacent) to the first pixel circuit area in a first direction, an active layer disposed on the substrate and including: first and second active patterns overlapping the first pixel circuit area and spaced apart from each other, and a third active pattern overlapping the second pixel circuit area and spaced apart from the first and second active patterns, a first gate layer disposed on the active layer and including: a gate electrode constituting a driving transistor that generates a driving current together with a portion of the second active pattern, a first gate signal line to which a first write gate signal is applied, extending in a second direction intersecting the first direction, and constituting a first-first switching transistor together with the first active pattern, and a second signal line to which a second write gate signal is applied, extending in the second direction, constituting a second-first switching transistor together with another portion of the second active pattern, the second-first switching transistor facing the first-first switching transistor with the driving transistor in between in a plan view, and constituting a second switching transistor together with the third active pattern, a second gate layer disposed on the first gate layer, a first data conductive layer disposed on the second gate layer, and a second data conductive layer disposed on the first data conductive layer.

In an embodiment, the first data conductive layer may include a connection pattern connected to a first area doped with impurities of the first active pattern through a first contact hole and connected to a second area doped with impurities of the second active pattern through a second contact hole.

In an embodiment, the gate electrode may overlap a third area doped with impurities of the first active pattern, and a fourth area doped with impurities of the second active pattern may be disposed between the gate electrode and the second area of the second active pattern in the plan view.

In an embodiment, the date line may overlap the connection pattern in the plan view and constituting a program capacitor together with the connection pattern.

In an embodiment, a portion of the second active pattern overlapping the gate electrode may have a U-shape in the plan view.

In an embodiment, the second gate layer may include an initialization voltage line overlapping the gate electrode in the plan view and constituting a storage capacitor together with the gate electrode.

In an embodiment, the initialization voltage line may extend in the second direction.

In the display device in embodiments of the disclosure, in one pixel circuit area, a third transistor may be disposed to face a second transistor with a first transistor in between in a plan view. The second transistor disposed in a first pixel circuit area disposed in a N-th pixel row and the third transistor disposed in a second pixel circuit area disposed in a (N+1)-th pixel row may be disposed on the same straight line. At this time, in one pixel circuit area, the second transistor may include a portion of a first gate signal line to which a N-th write gate signal is applied, and the third transistor may include a portion of a second gate signal line to which a (N+1)-th write gate signal is applied. In addition, a first active pattern (i.e., a drain electrode of the third transistor) and a second active pattern (i.e., a source electrode of the second transistor) may be connected through a connection pattern. Accordingly, a channel length of the first transistor may be reduced.

In addition, the connection pattern may constitute a program capacitor together with a data line. Accordingly, the program capacitor may secure sufficient capacitance.

### BRIEF DESCRIPTION OF THE DRAWINGS

Illustrative, non-limiting embodiments will be more clearly understood from the following detailed description in conjunction with the accompanying drawings.

FIG. 1 is a block diagram showing an embodiment of a display device according to the disclosure.

FIG. 2 is a circuit diagram showing pixels included in a display panel of FIG. 1.

FIG. 3 is a cross-sectional view schematically showing a display panel of FIG. 1.

FIGS. 4, 5, 6, 7, 8, 9, 10, 11, 12, 13, 14, 15, and 16 are plan views for explaining components of first, second, third, and fourth pixel circuits of pixels included in the display panel of FIG. 1.

FIG. 17 is a cross-sectional view taken along line I-I′ of FIG. 14.

FIG. 18 is a block diagram showing an electronic device according to embodiments of the present disclosure.

FIG. 19 are schematic diagrams showing an electronic device according to various embodiments.

### DETAILED DESCRIPTION

Hereinafter, a display device in embodiments of the disclosure will be explained in detail with reference to the accompanying drawings. The same reference numerals are used for the same components in the drawings, and redundant descriptions of the same components will be omitted.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

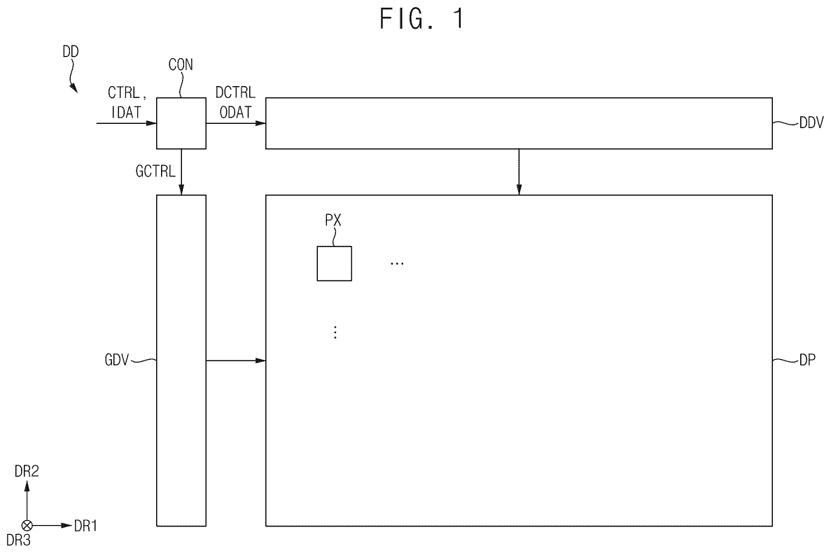

FIG. 1 is a block diagram showing an embodiment of a display device according to the disclosure.

Referring to FIG. 1, the display device DD in an embodiment of the disclosure may include a display panel DP, a data driver DDV, a gate driver GDV, and a timing controller CON.

The display device DD may display an image through the display panel DP. In an embodiment, the display panel DP may include a plurality of pixels PX, each including a driving transistor and a light-emitting element electrically connected to the driving transistor, for example. The light-emitting element may emit light by receiving a driving current from the driving transistor. In this way, the display device DD may display an image by the plurality of pixels PX that emits light.

One pixel PX may display one predetermined basic color. In other words, one pixel PX may be the minimum unit capable of displaying a color independent of other pixels PX. In an embodiment, one pixel PX may display any one color among red, green, and blue, for example.

The pixels PX may be arranged in a matrix form along a first direction DR1 and a second direction DR2 intersecting the first direction DR1. In an embodiment, the first direction DR1 and the second direction DR2 may be perpendicular, for example.

The timing controller CON may generate a gate control signal GCTRL, a data control signal DCTRL, and an output image data ODAT based on a control signal CTRL and an input image data IDAT provided from the outside. In an embodiment, the control signal CTRL may include a vertical synchronization signal, a horizontal synchronization signal, an input data enable signal, a master clock signal, or the like, for example. In an embodiment, the input image data IDAT may be red, green and blude (“RGB”) data including red image data, green image data, and blue image data, for example. In an alternative embodiment, the input image data IDAT may include magenta image data, cyan image data, and yellow image data, for example.

The gate driver GDV may generate gate signals based on the gate control signal GCTRL provided from the timing controller CON. In an embodiment, the gate control signal GCTRL may include a vertical start signal, a clock signal, or the like, for example. In an embodiment, the gate driver GDV may be manufactured as a separate panel and connected to the display panel DP, for example. The gate driver GDV may be electrically connected to the display panel DP and may sequentially output the gate signals. Each of the plurality of pixels PX may receive data voltages from the data driver DDV according to the control of each of the gate signals.

The data driver DDV may generate the data voltages based on the data control signal DCTRL and output image data ODAT provided from the timing controller CON. In an embodiment, the data control signal DCTRL may include an output data enable signal, a horizontal start signal, a load signal, or the like, for example. In an embodiment, the data driver DDV may be manufactured as a separate panel and electrically connected to the display panel DP, for example. Each of the plurality of pixels PX may transmit a signal for luminance corresponding to each of the data voltages to the light-emitting element.

In this specification, a plane may be defined in the first direction DR1 and the second direction DR2. In addition, a third direction DR3 may be perpendicular to the plane.

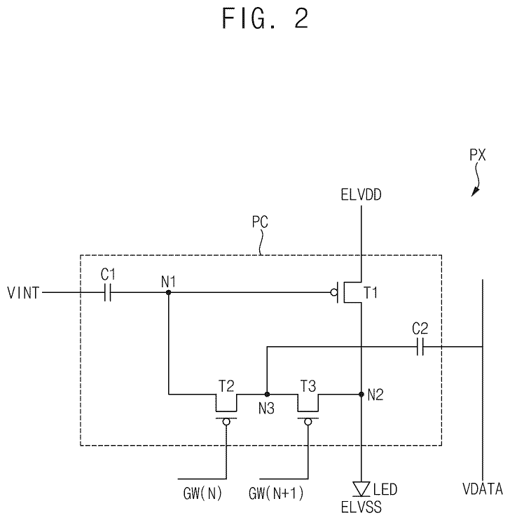

FIG. 2 is a circuit diagram showing pixels included in a display panel of FIG. 1.

Referring to FIG. 2, each pixel PX may include a pixel circuit PC and a light-emitting element LED electrically connected to the pixel circuit PC. In an embodiment, the pixel circuit PC may include first, second, and third transistors T1, T2, and T3, a first capacitor C1, and a second capacitor C2. The pixel circuit PC may generate a driving current, and the light-emitting element LED may emit light based on the driving current.

In an embodiment, the first, second, and third transistors T1, T2, and T3 may all be PMOS transistors. However, embodiments of the invention are not necessarily limited thereto, and at least some of the first, second, and third transistors T1, T2, and T3 may be NMOS transistors.

When the pixel circuit PC includes a p-channel metal-oxide-semiconductor (“PMOS”) transistor, an active pattern of the PMOS transistor may include a silicon semiconductor. However, embodiments of the invention are not necessarily limited thereto, and the active pattern of the PMOS transistor may include an oxide semiconductor.

The first transistor T1 may include a first electrode, a second electrode, and a gate electrode. The gate electrode of the first transistor T1 may be connected to a first node N1. A driving voltage ELVDD may be applied to the first electrode of the first transistor T1. The second electrode of the first transistor T1 may be connected to a second node N2. The first transistor T1 may provide the driving current to the light-emitting element LED.

The second transistor T2 may include a first electrode, a second electrode, and a gate electrode. In an embodiment, a N-th write gate signal GW(N) may be applied to the gate electrode of the second transistor T2. The first electrode of the second transistor T2 may be connected to a third node N3. The second electrode of the second transistor T2 may be connected to the first node N1. Here, the N-th write gate signal GW(N) refers to a write gate signal applied to the pixel circuit PC disposed in a N-th pixel row.

The third transistor T3 may include a first electrode, a second electrode, a gate electrode, and a back gate electrode. In an embodiment, a (N+1)-th write gate signal GW(N+1) may be applied to the gate electrode of the third transistor T3. The first electrode of the third transistor T3 may be connected to the second node N2. The second electrode of the third transistor T3 may be connected to the third node N3. Here, a (N+1)-th write gate signal GW(N+1) refers to a write gate signal applied to the pixel circuit PC disposed in a (N+1)-th pixel row.

In this specification, the N-th write gate signal GW(N) may be also referred to as a first write gate signal, and the (N+1)-th write gate signal GW(N+1) may be also referred to as a second write gate signal.

The second transistor T2 may be turned on or off in response to the N-th write gate signal GW(N), and the third transistor T3 may be turned on or off in response to the (N+1)-th write gate signal GW(N+1). In an embodiment, when the N-th write gate signal GW(N) and the (N+1)-th write gate signal GW(N+1) both have activation levels, the second transistor T2 and the third transistor T3 may all be turned on, for example. In this case, the second transistor T2 and the third transistor T3 may provide an initialization voltage VINT to the second node N2. In addition, the second transistor T2 may transmit the voltage of the third node N3 according to the data voltage VDATA to the first node N1.

Conversely, when the N-th write gate signal GW(N) has an activation level and the (N+1)-th write gate signal GW(N+1) has an inactivation level, the second transistor T2 may be turned on, and the third transistor T3 may be turned off. In this case, the second transistor T2 may transmit the voltage of the third node N3 according to the data voltage VDATA to the first node N1. However, the third transistor T3 may block the supply of the initialization voltage VINT.

Conversely, when both the N-th write gate signal GW(N) and the (N+1)-th write gate signal GW(N+1) both have inactivation levels, the second transistor T2 and the third transistor T3 may all be turned off. In this case, the second transistor T2 and the third transistor T3 may block the supply of the initialization voltage VINT. In addition, the second transistor T2 may block transmission of the data voltage VDATA to the first node N1.

As a result, the second transistor T2 and the third transistor T3 may operate together to initialize the voltage of the second node N2.

In an embodiment, the first electrode of each of the first, second, and third transistors T1, T2, and T3 may be a source electrode, and the second electrode may be a drain electrode. However, embodiments of the disclosure are not necessarily limited thereto.

The first capacitor C1 may include a first electrode and a second electrode. The initialization voltage VINT may be applied to the first electrode of the first capacitor C1. The second electrode of the first capacitor C1 may be connected to the first node N1. The first capacitor C1 may serve to store and maintain the voltage of the first node N1.

The second capacitor C2 may include a first electrode and a second electrode. The data voltage VDATA may be applied to the first electrode of the second capacitor C2. The second electrode of the second capacitor C2 may be connected to the third node N3.

The light-emitting element LED may include an anode electrode and a cathode electrode. The anode electrode of the light-emitting element LED may be connected to the second node N2. A common voltage ELVSS may be applied to the cathode electrode of the light-emitting element LED. The voltage level of the common voltage ELVSS may be lower than the voltage level of the driving voltage ELVDD. The light-emitting element LED may emit light based on the driving current.

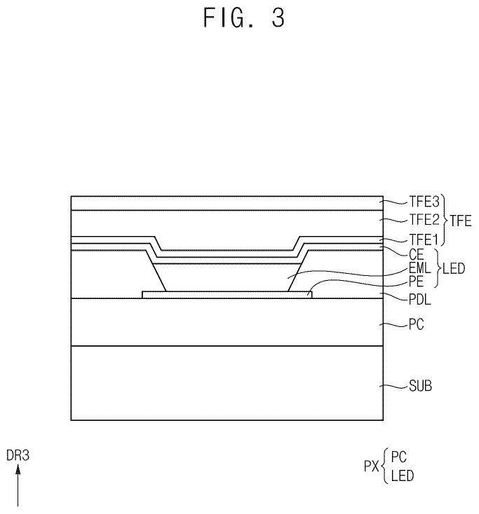

FIG. 3 is a cross-sectional view schematically showing a display panel of FIG. 1. In an embodiment, FIG. 3 is a cross-sectional view schematically showing an embodiment of a cross-section of each pixel PX of FIG. 1, for example.

Referring to FIG. 3, the display panel DP may include a substrate SUB, the pixel circuit PC, the light-emitting element LED, a pixel defining layer PDL, and an encapsulation layer TFE.

The substrate SUB may include a transparent material or an opaque material. The substrate SUB may include or consist of a transparent resin substrate. In embodiments, the transparent resin substrate may include a polyimide substrate. In this case, the polyimide substrate may include a first organic layer, a first barrier layer, a second organic layer, or the like. In an alternative embodiment, the substrate SUB may include a quartz substrate, synthetic quartz substrate, calcium fluoride substrate, F-doped quartz substrate, a soda-lime glass substrate, a non-alkali glass substrate, or the like. These may be used alone or in any combinations with each other.

The pixel circuit PC may be disposed on the substrate SUB. The pixel circuit PC may provide signals and voltages for the light-emitting element LED to emit light to the light-emitting element LED. In an embodiment, the pixel circuit PC may include a transistor, a conductive layer, an insulating layer, or the like, for example.

A pixel electrode PE may be disposed on the pixel circuit PC. The pixel electrode PE may receive the signals and voltages from the pixel circuit PC. In an embodiment, the pixel electrode PE may include metal, alloy, metal nitride, conductive metal oxide, transparent conductive material, or the like, for example. These may be used alone or in any combinations with each other. In an embodiment, the pixel electrode PE may be an anode electrode, for example.

The pixel defining layer PDL may be disposed on the pixel circuit PC and the pixel electrode PE. The pixel defining layer PDL may define an opening exposing at least a portion of the pixel electrode PE. As the pixel defining layer PDL defines the opening, the pixel defining layer PDL may define each pixel PX that emits light. The pixel defining layer PDL may include organic materials and/or inorganic materials. In embodiments, the organic materials that may be used as the pixel defining layer PDL may include photoresist, polyacrylic resin, polyimide resin, polyamide resin, siloxane resin, acrylic resin, epoxy resin, or the like. These may be used alone or in any combinations with each other.

A light-emitting layer EML may be disposed on the pixel electrode PE. Specifically, the light-emitting layer EML may be disposed in the opening of the pixel defining layer PDL. The light-emitting layer EML may include materials for emitting light. In an embodiment, the light-emitting layer EML may include an organic light-emitting material or an inorganic light-emitting material, for example.

A common electrode CE may be disposed on the pixel defining layer PDL and the light-emitting layer EML. In an embodiment, the common electrode CE may include metal, alloy, metal nitride, conductive metal oxide, transparent conductive material, or the like, for example. These may be used alone or in any combinations with each other. In an embodiment, the common electrode CE may be a cathode electrode, for example.

Accordingly, the light-emitting element LED including the pixel electrode PE, the light-emitting layer EML, and the common electrode CE may be disposed on the substrate SUB. The pixel circuit PC and the light-emitting element LED may form one pixel PX.

The encapsulation layer TFE may be disposed on the common electrode CE. The encapsulation layer TFE may protect the light-emitting element LED from external oxygen and moisture. The encapsulation layer TFE may include at least one inorganic layer and at least one organic layer. In an embodiment, the encapsulation layer TFE may include a first inorganic layer TFE1 disposed on the common electrode CE, an organic layer TFE2 disposed on the first inorganic layer TFE1, and a second inorganic layer TFE3 disposed on the organic layer TFE2, for example.

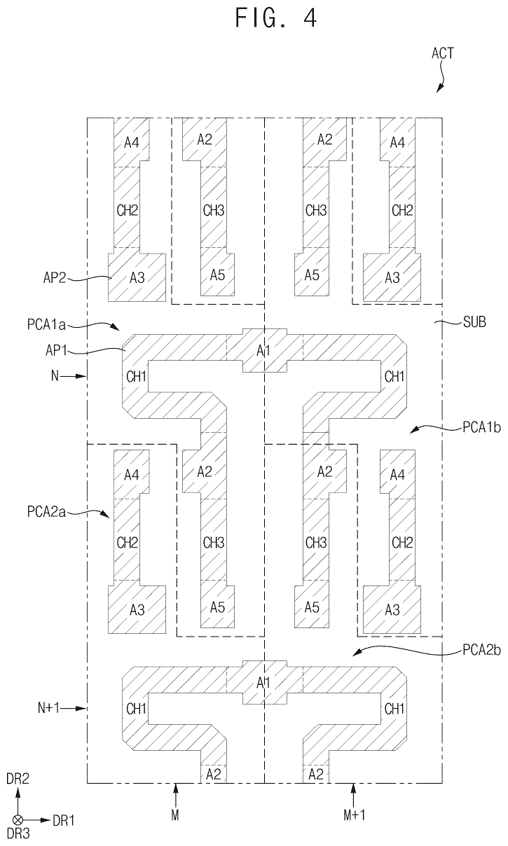

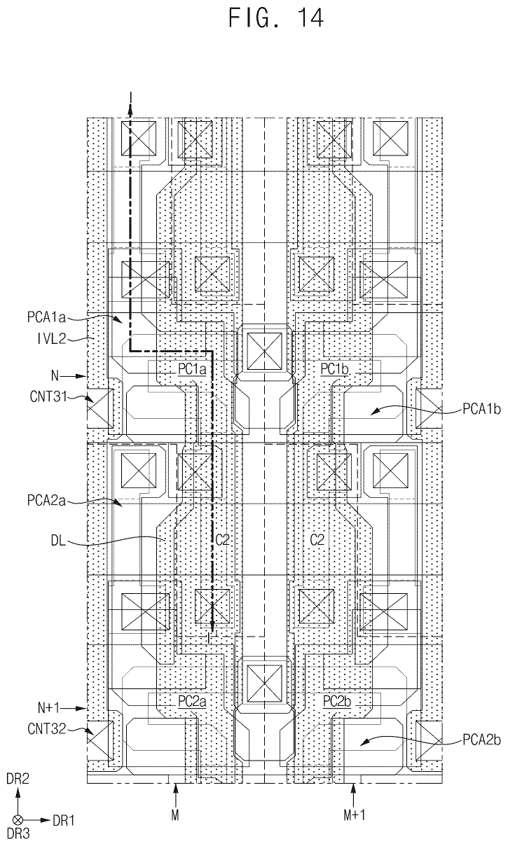

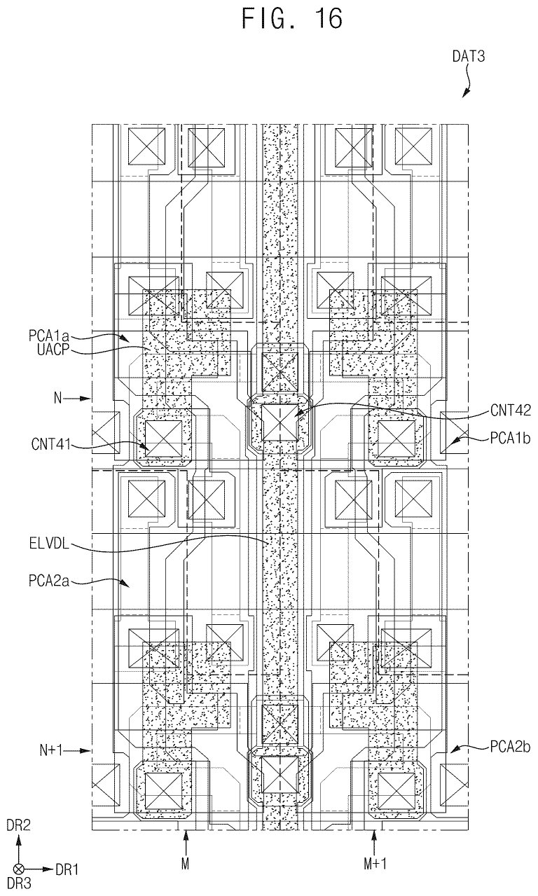

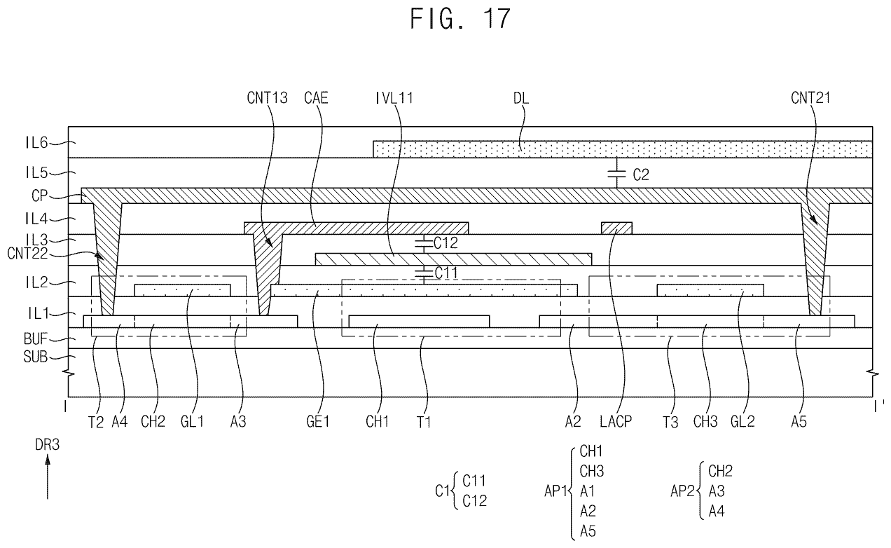

FIGS. 4, 5, 6, 7, 8, 9, 10, 11, 12, 13, 14, 15, and 16 are plan views for explaining components of first, second, third, and fourth pixel circuits of pixels included in the display panel of FIG. 1. FIG. 17 is a cross-sectional view taken along line I-I′ of FIG. 14. The light-emitting element LED of FIG. 3 may be disposed on the plan view shown in FIG. 16.

Referring to FIGS. 1 and 4, the display panel DP may include an active layer ACT disposed on the substrate SUB. Specifically, a buffer layer BUF (refer to FIG. 17) may be disposed on the substrate SUB, and the active layer ACT may be disposed on the buffer layer BUF. In an embodiment, the buffer layer BUF may include a silicon compound such as silicon oxide, silicon nitride, or the like, for example. These may be used alone or in any combinations with each other.

The substrate SUB may include a plurality of pixel circuit areas. In an embodiment, the pixel circuit areas may be arranged in a mattress shape along the first direction DR1 and the second direction DR2. The pixel circuit areas may include first, second, third, and fourth pixel circuit areas PCA1a, PCA2a, PCA1b, and PCA2b, for example.

The second pixel circuit area PCA2a may be next (adjacent) to the first pixel circuit area PCA1a in the opposite direction to the second direction DR2, and the fourth pixel circuit area PCA2b may be next (adjacent) to the third pixel circuit area PCA1b in the opposite direction to the second direction DR2. In addition, the first and third pixel circuit areas PCA1a and PCA1b may be arranged in the first direction DR1, and the second and fourth pixel circuit areas PCA2a and PCA2b may be also arranged in the first direction DR1. Specifically, the first pixel circuit area PCA1a may be disposed in a N-th pixel row and a M-th pixel column. The second pixel circuit area PCA2a may be disposed in a (N+1)-th pixel row and the M-th pixel column. The third pixel circuit area PCA1b may be disposed in the N-th pixel row and a (M+1)-th pixel column. The fourth pixel circuit area PCA2b may be disposed in the (N+1)-th pixel row and the (M+1)-th pixel column (where N and M are natural numbers).

In an embodiment, the (N+1)-th pixel row may be next (adjacent) to the N-th pixel row in the opposite direction to the second direction DR2, and the (M+1)-th pixel column may be next (adjacent) to the M-th pixel column in the first direction DR1, for example.

First, second, third, and fourth pixel circuits (e.g., first, second, third, and fourth pixel circuits PC1a, PC2a, PC1b, and PC2b of FIG. 14, respectively), which will be described later, may be disposed in the first, second, third, and fourth pixel circuit areas PCA1a, PCA2a, PCA1b, and PCA2b, respectively. The first pixel circuit may be substantially the same as (or similar to) the second pixel circuit, and the third pixel circuit may be substantially the same as (or similar to) the fourth pixel circuit. In addition, the pixel circuits arranged in the (M+1)-th pixel column may have a structure in which the structure of the pixel circuits arranged in the M-th pixel column is symmetrical with respect to a virtual symmetry line extending in the second direction DR2. Hereinafter, the description will focus on the first pixel circuit disposed in the first pixel circuit area PCA1a.

The active layer ACT may include a first active pattern AP1 and a second active pattern AP2. The first active pattern AP1 and the second active pattern AP2 may be spaced apart from each other.

The first active pattern AP1 and the second active pattern AP2 may be disposed in the same layer. In addition, the first active pattern AP1 and the second active pattern AP2 may include the same material and be formed through the same process.

The first active pattern AP1 may be disposed in each pixel row. In addition, the first active pattern AP1 may be disposed in every two pixel circuit areas (i.e., two pixel columns) next (adjacent) to each other in the first direction DR1. The second active pattern AP2 may be disposed in each pixel row and each pixel column.

The first active pattern AP1 may include a first area A1, a second area A2, a fifth area A5, a first channel area CH1, and a third channel area CH3. The first area A1, the second area A2, and the fifth area A5 may be spaced apart from each other. The first channel area CH1 may be disposed between the first area A1 and the second area A2, and the third channel area CH3 be disposed between the second area A2 and the fifth area A5.

The second active pattern AP2 may include a third area A3, a fourth area A4, and a second channel area CH2. The third area A3 and the fourth area A4 may be spaced apart from each other. The second channel area CH2 may be disposed between the third area A3 and the fourth area A4.

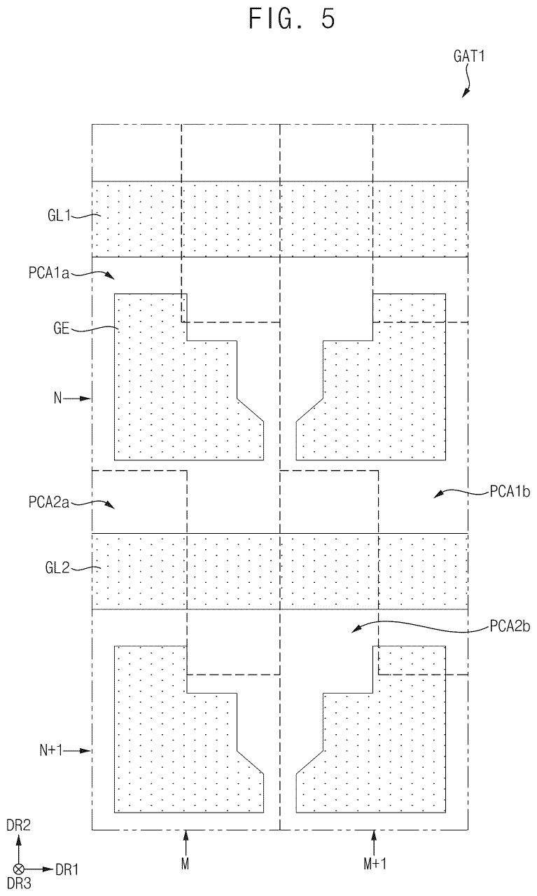

In an embodiment, the first, second, third, fourth, and fifth areas A1, A2, A3, A4, and A5 may be conductive areas doped with impurities (e.g., P-type impurities or N-type impurities) after the first gate layer GAT1 of FIG. 5 is formed, for example. In contrast, the first, second, and third channel areas CH1, CH2, and CH3 may be areas that are not doped with impurities.

In an embodiment, a portion of the first active pattern AP1 (i.e., the first channel area CH1) overlapping the gate electrode GE of FIG. 5 may have a U-shape in a plan view.

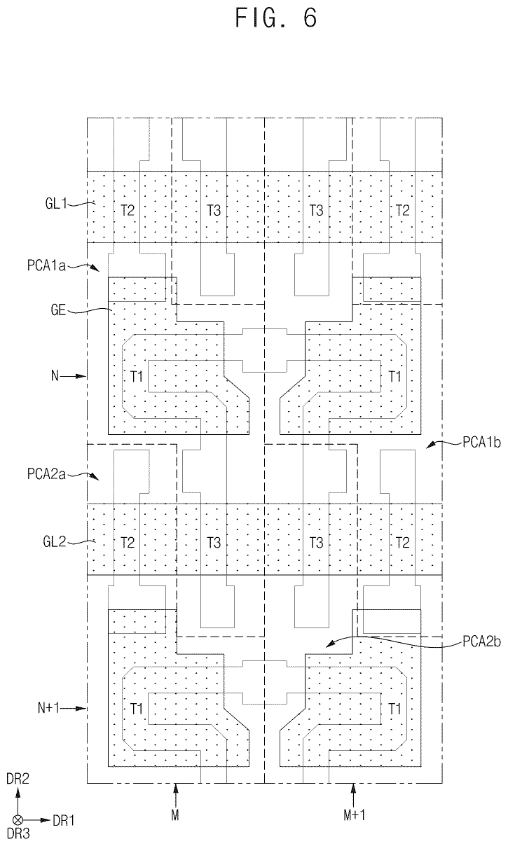

Accordingly, the channel length of the first transistor T1 of FIG. 6 may be reduced. In this case, high-resolution and high-integration of the display device (e.g., the display device DD of FIG. 1) may be realized. The second active pattern AP2 may have a shape extending in the second direction DR2 in the plan view.

In an embodiment, the active layer ACT may include a silicon semiconductor such as amorphous silicon, polycrystalline silicon, or the like. However, embodiments of the disclosure are not necessarily limited thereto, and the active layer ACT may include a metal oxide semiconductor.

Referring further to FIGS. 5 and 6, the display panel DP may further include a first gate layer GAT1 disposed on the active layer ACT. Specifically, a first insulating layer IL1 (refer to FIG. 17) may be disposed on the active layer ACT, and the first gate layer GAT1 may be disposed on the first insulating layer IL1. In an embodiment, the first insulating layer IL1 may include a silicon compound such as silicon oxide, silicon nitride, or the like, for example. These may be used alone or in any combinations with each other.

The first gate layer GAT1 may include a first gate signal line GL1, a second gate signal line GL2, and a gate electrode GE. The first gate signal line GL1, the second gate signal line GL2, and the gate electrode GE may be spaced apart from each other.

The first gate signal line GL1, the second gate signal line GL2, and the gate electrode GE may be disposed in the same layer. In addition, the first gate signal line GL1, the second gate signal line GL2, and the gate electrode GE may include the same material and be formed through the same process.

The gate electrode GE may be disposed in each pixel row and each pixel column. The first gate signal line GL1 may be disposed in the N-th pixel row. When the first gate signal line GL1 is disposed in the N-th pixel row, the second gate signal line GL2 may be disposed in the (N+1)-th pixel row.

The gate electrode GE may partially overlap the first active pattern AP1 in the plan view. In addition, the gate electrode GE may partially overlap the second active pattern AP2 in the plan view.

In an embodiment, a portion of the first active pattern AP1 (i.e., the first area A1, the first channel area CH1, and the second area A2) and the gate electrode GE overlapping the first channel area CH1 may constitute the first transistor T1. That is, the first transistor T1 may include the portion of the first active pattern AP1 and the gate electrode GE. The first transistor T1 may correspond to the first transistor T1 of FIG. 2. The first transistor T1 may be also referred to as a driving transistor.

The first gate signal line GL1 may partially overlap the first active pattern AP1 and the second active pattern AP2, respectively, in the plan view. The first gate signal line GL1 may extend in the first direction DR1. The first write gate signal (e.g., the N-th write gate signal GW(N) of FIG. 2) may be applied to the first gate signal line GL1. The first gate signal line GL1 may provide the first write gate signal to pixel circuits disposed in the N-th pixel row (e.g., the first and third pixel circuits corresponding to the first and third pixel circuit areas PCA1a and PCA1b of FIG. 14, respectively). In addition, the first gate signal line may also provide the first write gate signal to pixel circuits disposed in a (N−1)-th pixel row next (adjacent) to the N-th pixel row in the second direction DR2.

In an embodiment, the second active pattern (i.e., the third area A3, the second channel area CH2, and the fourth area A4) and a portion (i.e., a gate electrode) of the first gate signal line GL1 overlapping the second channel area CH2 of the second active pattern AP2 may constitute the second transistor T2. That is, the second transistor T2 may include the second active pattern AP2 and the portion of the first gate signal line GL1. The second transistor T2 may correspond to the second transistor T2 of FIG. 2. The second transistor T2 may be also referred to as a switching transistor.

The second gate signal line GL2 may partially overlap the first active pattern AP1 and the second active pattern AP2, respectively, in the plan view. The second gate signal line GL2 may extend in the first direction DR1. The second write gate signal (e.g., the (N+1)-th write gate signal GW(N+1) of FIG. 2) may be applied to the second gate signal line GL2. The second gate signal line GL2 may provide the second write gate signal to pixel circuits disposed in the N-th pixel row (e.g., the first and third pixel circuits corresponding to the first and third pixel circuit areas PCA1a and PCA1b of FIG. 14, respectively) and pixel circuits disposed in the (N+1)-th pixel row (e.g., the second and fourth pixel circuits corresponding to the second and fourth pixel circuit areas PCA2a and PCA2b of FIG. 14, respectively).

In an embodiment, another portion of the first active pattern AP1 (i.e., the second area A2, the third channel area CH3, and the fifth area A5) and a portion (i.e., gate electrode) of the second gate signal line GL2 overlapping the third channel area CH3 may constitute the third transistor T3. That is, the third transistor T3 may include another portion of the first active pattern AP1 and the portion of the second gate signal line GL2. The third transistor T3 may correspond to the third transistor T3 of FIG. 2. The third transistor T3 may be also referred to as a switching transistor.

In an embodiment, in one pixel circuit area, the third transistor T3 may be disposed to face the second transistor T2 with the first transistor T1 in between in the plan view. That is, in one pixel circuit area, the third transistor T3 may be disposed in a diagonal direction (e.g., a diagonal direction between the direction opposite to the first direction DR1 and the second direction DR2) with the second transistor T2 with the first transistor T1 in between.

In an embodiment, the second transistor T2 disposed in the first pixel circuit area PCA1a and the third transistor T3 disposed in the second pixel circuit area PCA2a may be disposed on the same straight line extending in the first direction DR1. Similarly, the second transistor T2 disposed in the third pixel circuit area PCA1b and the third transistor T3 disposed in the fourth pixel circuit area PCA2b may be disposed on the same straight line extending in the first direction DR1. That is, the second transistor T2 and the third transistor T3 may be alternately disposed along the second gate signal line GL2. Likewise, the second transistor T2 and the third transistor T3 may be alternately disposed along the first gate signal line GL1.

In an embodiment, the third transistor T3 disposed in the first pixel circuit area PCA1a may include a portion of the second gate signal line GL2 overlapping the first active pattern AP1, and the second transistor T2 disposed in the second pixel circuit area PCA2a may include a portion of the second gate signal line GL2 overlapping the second active pattern AP2. Likewise, the second transistor T2 disposed in the third pixel circuit area PCA1b may include a portion of the second gate signal line GL2 overlapping the second active pattern AP2, and the third transistor T3 disposed in the fourth pixel circuit area PCA2b may include a portion of the second gate signal line GL2 overlapping the first active pattern AP1.

Similarly, the second transistor T2 disposed in the first pixel circuit area PCA1a may include a portion of the first gate signal line GL1 overlapping the second active pattern AP2, and the third transistor T3 disposed in a pixel circuit area next (adjacent) to the first pixel circuit area PCA1a in the second direction DR2 may include a portion of the first gate signal line GL1 overlapping the first active pattern AP1. Likewise, the third transistor T3 disposed in the third pixel circuit area PCA1b may include a portion of the first gate signal line overlapping the first active pattern AP1, and the second transistor T2 disposed in a pixel circuit area next (adjacent) to the third pixel circuit area PCA1b in the second direction DR2 may include a portion of the first gate signal line GL1 overlapping the second active pattern AP2.

In an embodiment, the first gate layer GAT1 may include metal, alloy, metal nitride, conductive metal oxide, transparent conductive material, or the like, for example. These may be used alone or in any combinations with each other.

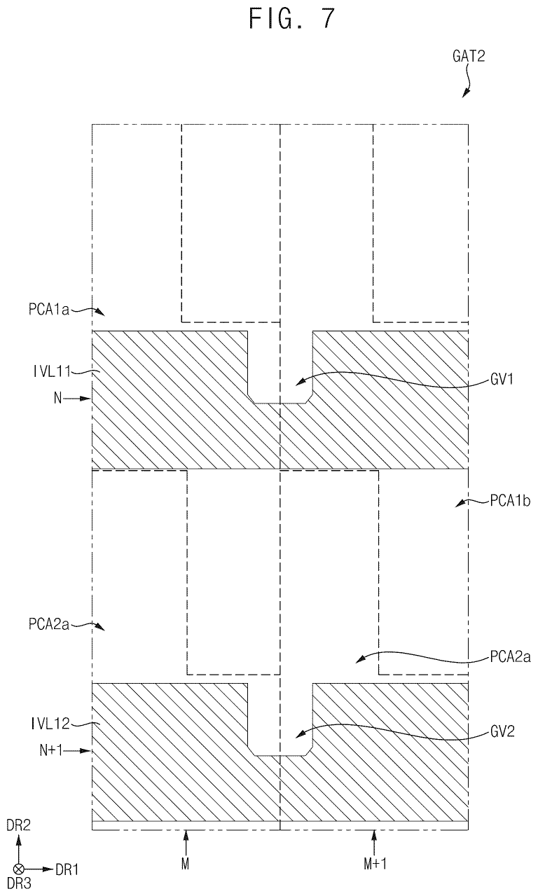

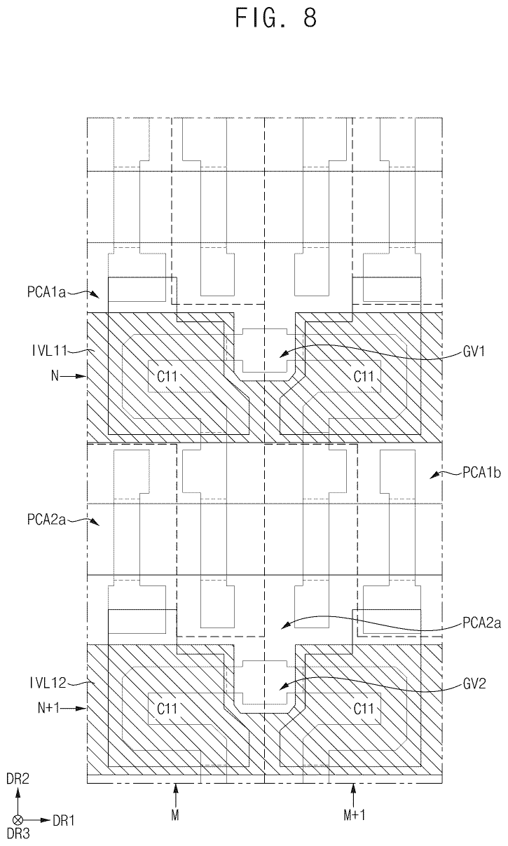

Referring further to FIGS. 7 and 8, the display panel DP may further include a second gate layer GAT2 disposed on the first gate layer GAT1. Specifically, a second insulating layer IL2 may be disposed on the first gate layer GAT1, and the second gate layer GAT2 may be disposed on the second insulating layer IL2. In an embodiment, the second insulating layer IL2 may include a silicon compound such as silicon oxide, silicon nitride, or the like, for example. These may be used alone or in any combinations with each other (refer to FIG. 17).

The second gate layer GAT2 may include a first-first initialization voltage line IVL11 and a first-second initialization voltage line IVL12. The first-first initialization voltage line IVL11 and the first-second initialization voltage line IVL12 may be spaced apart from each other.

The first-first initialization voltage line IVL11 and the first-second initialization voltage line IVL12 may be disposed in the same layer. In addition, the first-first initialization voltage line IVL11 and the first-second initialization voltage line IVL12 may include the same material and may be formed through the same process.

The first-first initialization voltage line IVL11 may be disposed in the N-th pixel row. When the first-first initialization voltage line IVL11 is disposed in the N-th pixel row, the first-second initialization voltage line IVL12 may be disposed in the (N+1)-th pixel row.

The first-first initialization voltage line IVL11 may extend in the first direction DR1. An initialization voltage (e.g., the initialization voltage VINT of FIG. 2) may be applied to the first-first initialization voltage line IVL11. Specifically, the first-first initialization voltage line IVL11 may provide an initialization voltage to the pixel circuits disposed in the N-th pixel row (i.e., the first and third pixel circuits corresponding to the first and third pixel circuit areas PCA1a and PCA1b of FIG. 14, respectively). A first groove GV1 may be defined in the first-first initialization voltage line IVL11. The first groove GV1 may expose at least a portion of the first area A1 of the first active pattern AP1 disposed in the N-th pixel row.

In the first pixel circuit area PCA1a and the third pixel circuit area PCA1b (i.e., in the N-th pixel row), the first-first initialization voltage line IVL11 may partially overlap the gate electrode GE in the plan view. Accordingly, the gate electrode GE and the portion of the first-first initialization voltage line IVL11 overlapping the gate electrode GE may form a first-first capacitor C11. That is, the first-first capacitor C11 may include the gate electrode GE and the portion of the first-first initialization voltage line IVL11 overlapping the gate electrode GE.

The first-second initialization voltage line IVL12 may extend in the first direction DR1. An initialization voltage (e.g., the initialization voltage VINT of FIG. 2) may be applied to the first-second initialization voltage line IVL12. Specifically, the first-second initialization voltage line IVL12 may provide the initialization voltage to the pixel circuits disposed in the (N+1)-th pixel row (i.e., the second and fourth pixel circuits corresponding to the second and fourth pixel circuit areas PCA2a and PCA2b of FIG. 14, respectively). A second groove GV2 may be defined in the first-second initialization voltage line IVL12. The second groove GV2 may expose at least a portion of the first area A1 of the first active pattern AP1 disposed in the (N+1)-th pixel row.

In the second pixel circuit area PCA2a and the fourth pixel circuit area PCA2b (i.e., in the (N+1)-th pixel row), the first-second initialization voltage line IVL12 may overlap partially the gate electrode GE in the plan view. Accordingly, the gate electrode GE and the portion of the first-second initialization voltage line IVL12 overlapping the gate electrode GE may constituting the first-first capacitor C11. In an embodiment, the capacitor formed by the gate electrode and the initialization voltage line may be also referred to as a storage capacitor, but is not limited thereto.

In an embodiment, the second gate layer GAT2 may include metal, alloy, metal nitride, conductive metal oxide, transparent conductive material, or the like, for example. These may be used alone or in any combinations with each other.

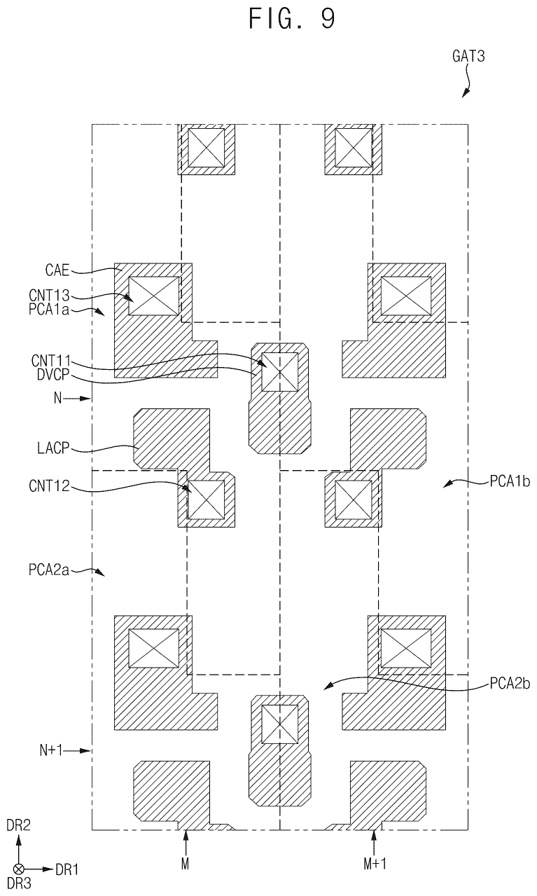

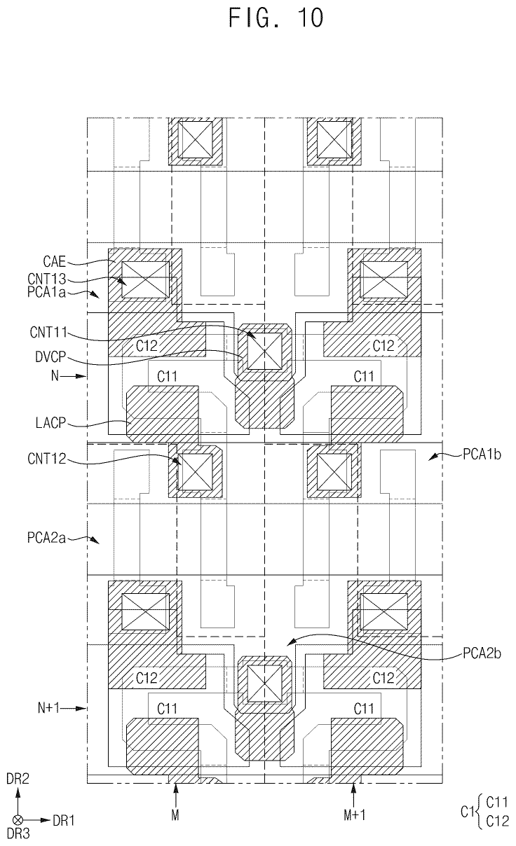

Referring further to FIGS. 9 and 10, the display panel DP may further include a third gate layer GAT3 disposed on the second gate layer GAT2. Specifically, a third insulating layer IL3 (refer to FIG. 17) may be disposed on the second gate layer GAT2, and the third gate layer GAT3 may be disposed on the third insulating layer IL3. In an embodiment, the third insulating layer IL3 may include a silicon compound such as silicon oxide, silicon nitride, or the like, for example. These may be used alone or in any combinations with each other.

The third gate layer GAT3 may include a lower anode connection pattern LACP, a capacitor electrode CAE, and a driving voltage connection pattern DVCP. The lower anode connection pattern LACP, the capacitor electrode CAE, and the driving voltage connection pattern DVCP may be spaced apart from each other.

The lower anode connection pattern LACP, the capacitor electrode CAE, and the driving voltage connection pattern DVCP may be disposed in the same layer. In addition, the lower anode connection pattern LACP, the capacitor electrode CAE, and the driving voltage connection pattern DVCP may include the same material and may be formed through the same process.

Each of the lower anode connection pattern LACP and the capacitor electrode CAE may be disposed in each pixel row and each pixel column. The driving voltage connection pattern DVCP may be disposed in every two pixel circuit areas (i.e., two pixel columns) next (adjacent) to each other in the first direction DR1.

The driving voltage connection pattern DVCP may be connected to the first area A1 of the first active pattern AP1 through a first-first contact hole CNT11. The first-first contact hole CNT11 may overlap the first groove GV1 of the first-first initialization voltage line IVL11 in the plan view. Accordingly, the driving voltage connection pattern DVCP may be electrically connected to the first transistor T1.

The lower anode connection pattern LACP may be connected to the second area A2 of the first active pattern AP1 through a first-second contact hole CNT12. Accordingly, the lower anode connection pattern LACP may be electrically connected to the first transistor T1 and the third transistor T3.

In the first pixel circuit area PCA1a and the third pixel circuit area PCA1b (i.e., in the N-th pixel row), the lower anode connection pattern LACP may overlap partially the first-first initialization voltage line IVL11 in the plan view. Likewise, in the second pixel circuit area PCA2a and the fourth pixel circuit area PCA2b (i.e., in the (N+1)-th pixel row), the lower anode connection pattern LACP may overlap partially to the first-second initialization voltage line IVL12.

The capacitor electrode CAE may be connected to the third area A3 of the second active pattern AP2 through a first-third contact hole CNT13. Accordingly, the capacitor electrode CAE may be electrically connected to the second transistor T2.

In the first pixel circuit area PCA1a and the third pixel circuit area PCA1b (i.e., in the N-th pixel row), the capacitor electrode CAE may partially overlap the first-first initialization voltage line IVL11 in the plan view. Accordingly, a portion of the capacitor electrode CAE and a portion of the first-first initialization voltage line IVL11 overlapping the portion of the capacitor electrode CAE may constitute a first-second capacitor C12. That is, the first-second capacitor C12 may include the portion of the capacitor electrode CAE and the portion of the first-first initialization voltage line IVL11 overlapping the portion of the capacitor electrode CAE.

Likewise, in the second pixel circuit area PCA2a and the fourth pixel circuit area PCA2b (i.e., in the (N+1)-th pixel row), the capacitor electrode CAE may partially overlap the first-second initialization voltage line IVL12 in the plan view. Accordingly, the portion of the capacitor electrode CAE and the portion of the first-second initialization voltage line IVL12 overlapping the portion of the capacitor electrode CAE may constitute the first-second capacitor C12. That is, the first-second capacitor C12 may include the portion of the capacitor electrode CAE and the portion of the first-second initialization voltage line IVL12 overlapping the portion of the capacitor electrode CAE.

Accordingly, the first-second capacitor C12 may constitute the first capacitor C1 together with the first-first capacitor C11. The first capacitor C1 may correspond to the first capacitor C1 of FIG. 2.

In an embodiment, the third gate layer GAT3 may include metal, alloy, metal nitride, conductive metal oxide, transparent conductive material, or the like, for example. These may be used alone or in any combinations with each other.

However, embodiments of the disclosure are not limited to this, and the third gate layer GAT3 may be omitted. In this case, the first capacitor C1 may constituted only of the gate electrode GE and an initialization voltage line (i.e., the first-first initialization voltage line IVL11 or the first-second initialization voltage line IVL12).

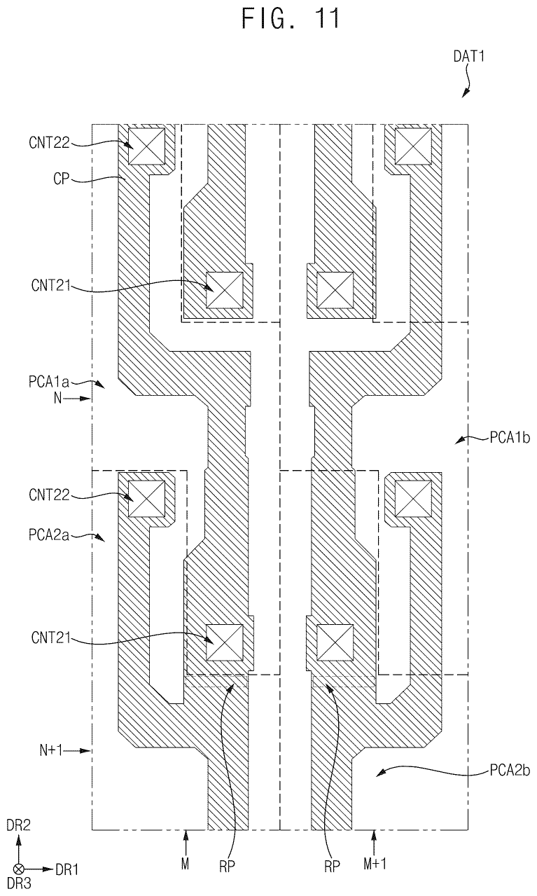

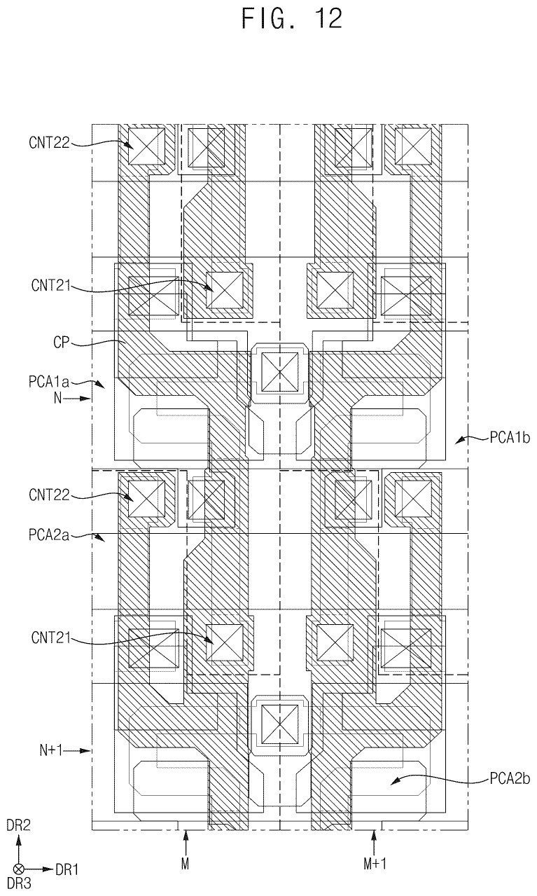

Referring further to FIGS. 11 and 12, the display panel DP may further include a first data conductive layer DAT1 disposed on the third gate layer GAT3. Specifically, a fourth insulating layer IL4 (refer to FIG. 17) may be disposed on the third gate layer GAT3, and the first data conductive layer DAT1 may be disposed on the fourth insulating layer IL4. In an embodiment, the fourth insulating layer IL4 may include a silicon compound such as silicon oxide, silicon nitride, or the like, for example. These may be used alone or in any combinations with each other. The first data conductive layer DAT1 may include a connection pattern CP.

In an embodiment, the connection pattern CP may connect the fifth area A5 (i.e., the drain electrode of the third transistor T3) of the first active pattern AP1 and the fourth area A4 (i.e., the source electrode of the second transistor T2) of the second active pattern AP2. Specifically, the connection pattern CP may be connected to the fifth area A5 of the first active pattern AP1 through a second-first contact hole CNT21, and may be connected to the fourth area 4 of the second active pattern AP2 through a second-second contact hole CNT22. Accordingly, the third transistor T3 and the second transistor T2 may be electrically connected through the connection pattern CP.

In an embodiment, as shown in FIGS. 11 and 12, the connection pattern CP may be formed integrally with each of two next (adjacent) pixel circuit areas in the second direction DR2, for example. In an embodiment, a portion of the connection pattern CP disposed in the first pixel circuit area PCA1a and a portion of the connection pattern CP disposed in the second pixel circuit area PCA2a may be formed integrally, for example. In an alternative embodiment, the connection pattern CP may be independently disposed for each pixel circuit area. In an embodiment, an area (i.e., a removal area RP) of the connection pattern CP between the first pixel circuit area PCA1a and the second pixel circuit area PCA2a may be removed, for example. In this case, a portion of the connection pattern CP disposed in the first pixel circuit area PCA1a and a portion of the connection pattern CP disposed in the second pixel circuit area PCA2a may be spaced apart from each other.

In an embodiment, the first data conductive layer DAT1 may include metal, alloy, metal nitride, conductive metal oxide, transparent conductive material, or the like, for example. These may be used alone or in any combinations with each other.

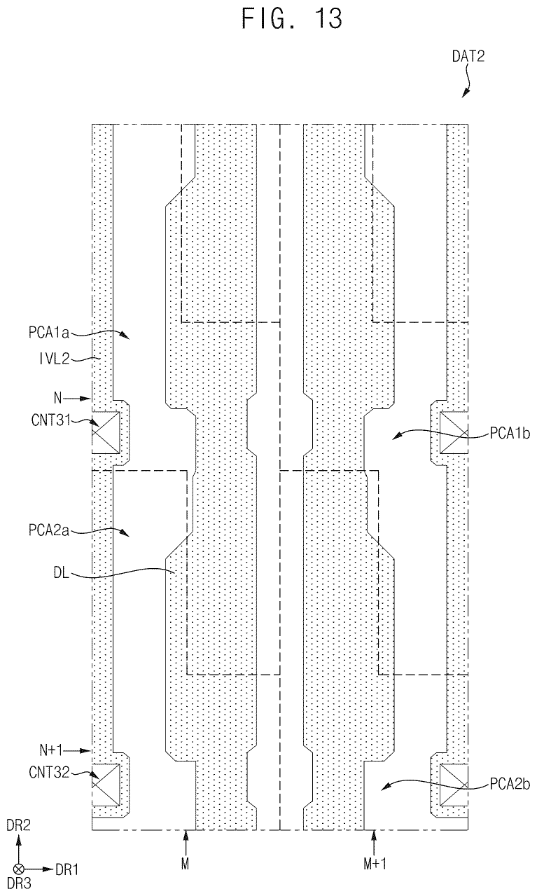

Referring further to FIGS. 13 and 14, the display panel DP may further include a second data conductive layer DAT2 disposed on the first data conductive layer DAT1. Specifically, a fifth insulating layer IL5 (refer to FIG. 17) may be disposed on the first data conductive layer DAT1, and the second data conductive layer DAT2 may be disposed on the fifth insulating layer IL5. In an embodiment, the fifth insulating layer IL5 may include a silicon compound such as silicon oxide, silicon nitride, or the like, for example. These may be used alone or in any combinations with each other.

The second data conductive layer DAT2 may include a second initialization voltage line IVL2 and a data line DL. The second initialization voltage line IVL2 and the data line DL may be spaced apart from each other.

The second initialization voltage line IVL2 and the data line DL may be disposed in the same layer. In addition, the second initialization voltage line IVL2 and the data line DL may include the same material and be formed through the same process.

The second initialization voltage line IVL2 may be disposed in each pixel column. Likewise, the data line DL may also be disposed for each pixel column.

The second initialization voltage line IVL2 may extend in the second direction DR2. The initialization voltage may be applied to the second initialization voltage line IVL2. The second initialization voltage line IVL2 may be connected to the first-first initialization voltage line IVL11 and the first-second initialization voltage line IVL12. Specifically, the second initialization voltage line IVL2 may be connected to the first-first initialization voltage line IVL11 through a third-first contact hole CNT31, and may be connected to the first-second initialization voltage line IVL12 through a third-second contact hole CNT32.

The data line DL may extend in the second direction DR2. A data voltage (e.g., the data voltage VDATA of FIG. 2) may be applied to the data line DL.

The data line DL may partially overlap the connection pattern CP in the plan view. Accordingly, a portion of the data line DL and a portion of the connection pattern CP overlapping the portion of the data line DL may constitute the second capacitor C2. That is, the second capacitor C2 may include the portion of the data line DL and the portion of the connection pattern CP overlapping the portion of the data line DL. The second capacitor C2 may correspond to the second capacitor C2 of FIG. 2.

Accordingly, the first, second, third, and fourth pixel circuits corresponding to the first, second, third, and fourth pixel circuit areas PCA1a, PCA2a, PCA1b, and PCA2b, respectively, may be formed in the first, second, third, and fourth pixel circuit areas PCA1a, PCA2a, PCA1b, and PCA2b, respectively. Each of the first, second, third, and fourth pixel circuits corresponding to the first, second, third, and fourth pixel circuit areas PCA1a, PCA2a, PCA1b, and PCA2b, respectively, may include the first, second, and third transistors T1, T2, and T3, the first capacitor C1, and the second capacitor C2.

In an embodiment, the second data conductive layer DAT2 may include metal, alloy, metal nitride, conductive metal oxide, transparent conductive material, or the like, for example. These may be used alone or in any combinations with each other.

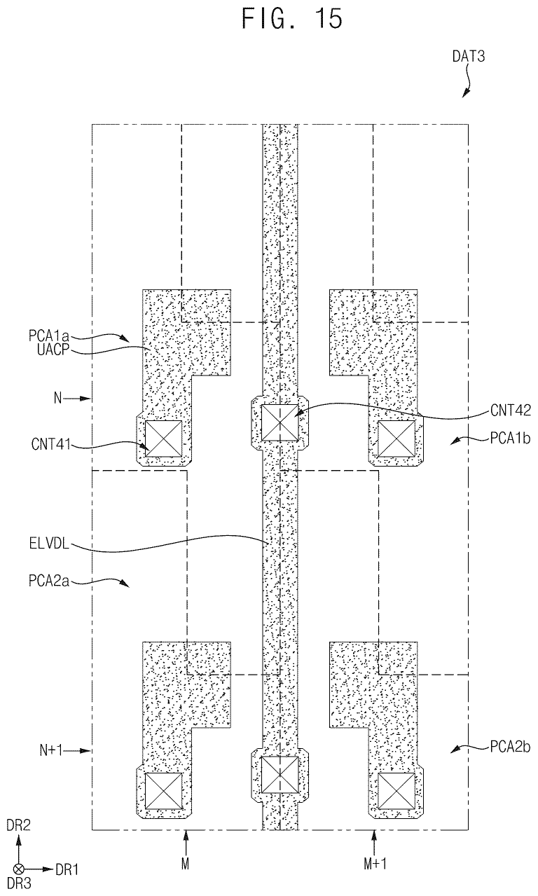

Referring further to FIGS. 15 and 16, the display panel DP may further include a third data conductive layer DAT3 disposed on the second data conductive layer DAT2. Specifically, a sixth insulating layer IL6 (refer to FIG. 17) may be disposed on the second data conductive layer DAT2, and the third data conductive layer DAT3 may be disposed on the sixth insulating layer IL6. In an embodiment, the sixth insulating layer IL6 may include a silicon compound such as silicon oxide, silicon nitride, or the like, for example. These may be used alone or in any combinations with each other.

The third data conductive layer DAT3 may include an upper anode connection pattern UACP and a driving voltage line ELVDL. The upper anode connection pattern UACP and the driving voltage line ELVDL may be arranged to be spaced apart from each other.

The upper anode connection pattern UACP and the driving voltage line ELVDL may be disposed in the same layer. Additionally, the upper anode connection pattern UACP and the driving voltage line ELVDL may include the same material and be formed through the same process.

The upper anode connection pattern UACP may be disposed for each pixel row and each pixel column. The driving voltage line ELVDL may be disposed in every two pixel circuit areas (i.e., two pixel columns) next (adjacent) to each other in the first direction DR1.

The upper anode connection pattern UACP may be connected to the lower anode connection pattern LACP through a fourth-first contact hole CNT41. In addition, the upper anode connection pattern UACP may be connected to a pixel electrode (e.g., the pixel electrode PE of FIG. 3) through a contact hole. In this case, the pixel electrode may be electrically connected to the second area A2 of the first active pattern AP1 through the upper anode connection pattern UACP and the lower anode connection pattern LACP. Accordingly, the pixel circuits corresponding to the pixel circuit areas PCA1a, PCA2a, PCA1b, and PCA2b, respectively, and a light-emitting element (e.g., the light-emitting element LED of FIG. 3) including the pixel electrode may be electrically connected.

The driving voltage line ELVDL may extend in the second direction DR2. A driving voltage (e.g., the driving voltage ELVDD of FIG. 2) may be applied to the driving voltage line ELVDL. The driving voltage line ELVDL may be connected to the driving voltage connection pattern DVCP through a fourth-second contact hole CNT42. Accordingly, the driving voltage line ELVDL may provide the driving voltage to the first area A1 of the first active pattern AP1 through the driving voltage connection pattern DVCP.

In an embodiment, the third data conductive layer DAT3 may include metal, alloy, metal nitride, conductive metal oxide, transparent conductive material, or the like, for example. These may be used alone or in any combinations with each other.

An organic insulating layer may be disposed on the third data conductive layer DAT3. In an embodiment, the organic insulating layer may include photoresist, polyacryl-based resin, polyimide-based resin, polyamide-based resin, siloxane-based resin, acryl-based resin, epoxy-based resin, or the like, for example. These may be used alone or in any combinations with each other.

The pixel defining layer PDL and the light-emitting element LED of FIG. 3 may be disposed on the organic insulating layer.

Referring back to FIGS. 1, 2, 3, 4, 5, 6, 7, 8, 9, 10, 11, 12, 13, 14, 15, 16, and 17, in the display device DD in embodiments of the disclosure, in one pixel circuit area, the third transistor T3 may be disposed to face the second transistor T2 with the first transistor T1 in between in the plan view. The second transistor T2 disposed in the first pixel circuit area PCA1a disposed in the N-th pixel row and the third transistor T3 disposed in a second pixel circuit area PCA2a disposed in the (N+1)-th pixel row may be disposed on the same straight line. At this time, in one pixel circuit area, the second transistor T2 may include the portion of the first gate signal line GL1 to which the N-th write gate signal GW(N) is applied, and the third transistor T3 may include the portion of the second gate signal line GL2 to which the (N+1)-th write gate signal GW(N+1) is applied. In addition, the first active pattern AP1 (i.e., the drain electrode of the third transistor T3) and the second active pattern AP2 (i.e., the source electrode of the second transistor T2) may be connected through the connection pattern CP. Accordingly, the channel length of the first transistor T1 may be reduced.

In addition, the connection pattern CP may constitute the program capacitor (i.e., the second capacitor C2) together with the data line DL. Accordingly, the program capacitor may secure sufficient capacitance.

As a result, as the channel length of the first transistor T1 is reduced and the program capacitor secures sufficient capacitance, high-resolution and high-integration of the display device DD may be realized.

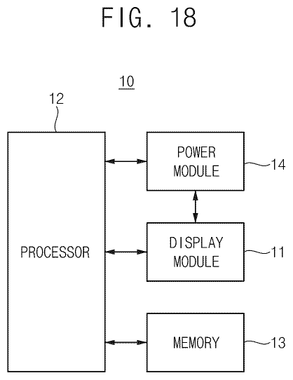

FIG. 18 is a block diagram showing an electronic device according to embodiments of the present disclosure.

Referring to FIG. 18, an electronic device 10 may include a display module 11, a processor 12, a memory 13, and a power module 14.

A display device (e.g., the display device DD of FIGS. 1 to 17) according to embodiments may be applied to various electronic devices 10. The electronic device 10 may include the display device described above, and may further include modules or devices with additional functions other than the display device.

The processor 12 may include at least one of a central processing unit (CPU), an application processor (AP), a graphic processing unit (GPU), a communication processor (CP), an image signal processor (ISP), and a controller. The processor 12 may control the display device.

The memory 15 may store data information necessary for the operation of the processor 12 or the display module 11. When the processor 12 executes the application stored in the memory 15, an image data signal and/or an input control signal may be transmitted to the display module 11, and the display module 11 may process the received signal and output image information through a display screen.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

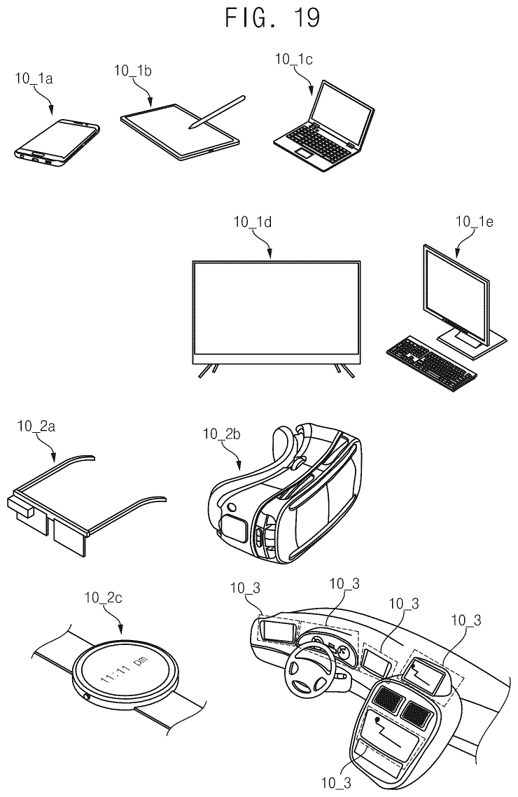

FIG. 19 are schematic diagrams showing an electronic device according to various embodiments.

Referring to FIG. 19, various electronic devices 10 to which display devices (e.g., the display device DD of FIGS. 1 to 17) according to the embodiments are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

The disclosure may be applied to various display devices. In an embodiment, the disclosure is applicable to various display devices such as display devices for vehicles, ships and aircraft, portable communication devices, display devices for exhibition or information transmission, medical display devices, or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims. Therefore, it is to be understood that the foregoing is illustrative of various embodiments and is not to be construed as limited to the illustrative embodiments disclosed, and that modifications to the disclosed embodiments, as well as other embodiments, are intended to be included within the scope of the appended claims.

What is claimed is:

1. A display device comprising:
a first pixel circuit including:
a first driving transistor which generates a driving current;
a first-first switching transistor including a first active pattern and a portion of a first gate signal line overlapping the first active pattern; and
a second-first switching transistor including a portion of a second active pattern spaced apart from the first active pattern and a portion of a second gate signal line overlapping the second active pattern, and facing the first-first switching transistor with the first driving transistor in between in a plan view;
a second pixel circuit next to the first pixel circuit in a first direction and including:
a second driving transistor which generates a driving current; and
a second switching transistor including a third active pattern spaced apart from the first active pattern and the second active pattern and a portion of the second gate signal line overlapping the third active pattern; and
a light-emitting element disposed on the first and second pixel circuits.

2. The display device of claim 1, wherein the first pixel circuit is disposed in a N-th pixel row, where N is a natural number, the second pixel circuit is disposed in a (N+1)-th pixel row next to the N-th pixel row,
the first gate signal line provides a first write gate signal to the first pixel circuit, and the second gate signal line provides a second write gate signal to the first and second pixel circuits.

3. The display device of claim 1, wherein each of the first gate signal line and the second gate signal line extends in a second direction crossing the first direction.

4. The display device of claim 1, wherein the first driving transistor includes:
another portion of the second active pattern; and
a gate electrode disposed on the second active pattern and overlapping the second active pattern.

5. The display device of claim 4, wherein the first active pattern includes a third area and a fourth area doped with impurities and spaced apart from each other and the second active pattern includes a first area, a second area, and a fifth area doped with impurities and spaced apart from each other,
further comprising:
a connection pattern connected to the fourth area of the first active pattern through a first contact hole and connected to the fifth area of the second active pattern through a second contact hole.

6. The display device of claim 5, wherein the portion of the second active pattern of the second-first switching transistor includes the second area and the fifth area, another portion of the second active pattern of the first driving transistor includes the first area and the second area,
the gate electrode overlaps the third area of the first active pattern in the plan view, and
the second area of the second active pattern is disposed between the gate electrode and the fifth area of the second active pattern in the plan view.

7. The display device of claim 5, wherein the connection pattern is disposed on the first and second gate signal lines.

8. The display device of claim 5, wherein the first pixel circuit further includes:
a program capacitor including the connection pattern and a portion of a data line disposed on the connection pattern and overlapping the connection pattern in the plan view.

9. The display device of claim 4, wherein a portion of the second active pattern overlapping the gate electrode has a U-shape in the plan view.

10. The display device of claim 4, wherein the first pixel circuit further includes:
a storage capacitor including the gate electrode and a portion of an initialization voltage line disposed on the gate electrode and overlapping the gate electrode in the plan view.

11. The display device of claim 10, wherein the storage capacitor further includes:
a portion of a capacitor electrode connected to the first active pattern through a contact hole and overlapping the initialization voltage line in the plan view.

12. The display device of claim 10, wherein the initialization voltage line extends in a second direction intersecting the first direction.

13. The display device of claim 1, wherein the first, second, and third active patterns include a silicon semiconductor.

14. A display device comprising:
a substrate including a first pixel circuit area and a second pixel circuit area next to the first pixel circuit area in a first direction;
an active layer disposed on the substrate and including:
first and second active patterns overlapping the first pixel circuit area and spaced apart from each other; and
a third active pattern overlapping the second pixel circuit area and spaced apart from the first and second active patterns;
a first gate layer disposed on the active layer and including:
a gate electrode constituting a driving transistor which generates a driving current together with a portion of the second active pattern;
a first gate signal line to which a first write gate signal is applied, extending in a second direction intersecting the first direction, and constituting a first-first switching transistor together with the first active pattern; and
a second signal line to which a second write gate signal is applied, extending in the second direction, constituting a second-first switching transistor together with another portion of the second active pattern, the second-first switching transistor facing the first-first switching transistor with the driving transistor in between in a plan view, and constituting a second switching transistor together with the third active pattern;
a second gate layer disposed on the first gate layer;
a first data conductive layer disposed on the second gate layer; and
a second data conductive layer disposed on the first data conductive layer.

15. The display device of claim 14, wherein the first data conductive layer includes:
a connection pattern connected to a first area doped with impurities of the first active pattern through a first contact hole and connected to a second area doped with impurities of the second active pattern through a second contact hole.

16. The display device of claim 15, wherein the gate electrode overlaps a third area doped with impurities of the first active pattern, and
a fourth area doped with impurities of the second active pattern is disposed between the gate electrode and the second area of the second active pattern in the plan view.

17. The display device of claim 15, wherein the date line overlaps the connection pattern in the plan view and constituting a program capacitor together with the connection pattern.

18. The display device of claim 14, wherein a portion of the second active pattern overlapping the gate electrode has a U-shape in the plan view.

19. The display device of claim 14, wherein the second gate layer includes:
an initialization voltage line overlapping the gate electrode in the plan view and constituting a storage capacitor together with the gate electrode.

20. The display device of claim 19, wherein the initialization voltage line extends in the second direction.

21. An electronic device comprising:
a display device comprising:
a first pixel circuit including:
a first driving transistor which generates a driving current;
a first-first switching transistor including a first active pattern and a portion of a first gate signal line overlapping the first active pattern; and
a second-first switching transistor including a portion of a second active pattern spaced apart from the first active pattern and a portion of a second gate signal line overlapping the second active pattern, and facing the first-first switching transistor with the first driving transistor in between in a plan view;
a second pixel circuit next to the first pixel circuit area in a first direction and including:
a second driving transistor which generates a driving current; and
a second switching transistor including a third active pattern spaced apart from the first active pattern and the second active pattern and a portion of the second gate signal line overlapping the third active pattern; and
a light-emitting element disposed on the first pixel circuit and the second pixel circuit; and
a processor which transfers an image data signal and an input control signal to the display device.

22. The electronic device of claim 21, wherein the first pixel circuit is disposed in a N-th pixel row, where Nis a natural number, the second pixel circuit is disposed in a (N+1)-th pixel row next to the N-th pixel row,
the first gate signal line provides a first write gate signal to the first pixel circuit area, and the second gate signal line provides a second write gate signal to the first and second pixel circuit areas.

23. The electronic device of claim 21, wherein each of the first gate signal line and the second gate signal line extends in a second direction crossing the first direction.

24. The electronic device of claim 21, wherein the first driving transistor includes:
another portion of the second active pattern; and
a gate electrode disposed on the second active pattern and overlapping the second active pattern.

25. The electronic device of claim 24, wherein the first active pattern includes a third area and a fourth area doped with impurities and spaced apart from each other and the second active pattern includes a first area, a second area, and a fifth area doped with impurities and spaced apart from each other,
further comprising:
a connection pattern connected to the fourth area of the first active pattern through a first contact hole and connected to the fifth area of the second active pattern through a second contact hole.

26. The electronic device of claim 25, wherein the portion of the second active pattern of the second-first switching transistor includes the second area and the fifth area, another portion of the second active pattern of the first driving transistor includes the first area and the second area,
the gate electrode overlaps the third area of the first active pattern in the plan view, and
the second area of the second active pattern is disposed between the gate electrode and the fifth area of the second active pattern in the plan view.
